(19) United States
(12) Patent Application Publication
(10) Pub. No.: US 2007/0234162 A1
(43) Pub. Date: Oct. 4, 2007

(54) Integrated Semiconductor Memory and Methods for Testing and Operating the Same

(75) Inventor: Roland Barth, Munchen (DE)

Correspondence Address: EDELL, SHAPIRO & FINNAN, LLC, 1901 RESEARCH BLVD., SUITE 400, ROCKVILLE, MD, 20850, US

(73) Assignee: Qimonda AG, Munich (DE)

(21) Appl. No.: 11/677,330

(22) Filed: Feb. 21, 2007

(30) Foreign Application Priority Data
Feb. 21, 2006 (DE) 102006008017.3

(51) Int. Cl. G06F 11/00; G01R 31/28

(52) U.S. Cl. 714/736

(57) ABSTRACT

In the context of functional tests a check is made to ascertain whether an integrated semiconductor memory satisfies specified operating parameters. In this case, operating parameters, such as the externally applied operating frequency or the externally applied operating voltage, are varied within specific limits. Integrated semiconductor memories which function without errors within a wide variation range of the operating parameters are classified as having high quality. Integrated semiconductor memories which, by contrast, function without any errors only in narrower tolerance ranges of the operating parameters are classified as having lower quality. During production of an integrated semiconductor memory, a data bit is stored in a memory circuit, the state of the data bit specifying whether the integrated semiconductor memory is of higher or lower quality. During operation of the integrated semiconductor memory, the quality of the semiconductor memory can be established by read-out of the memory circuit.

### CROSS REFERENCE TO RELATED APPLICATIONS

This application claims priority under 35 U.S.C. §119 to Application No. DE 102006008017.3 filed on Feb. 21, 2006, entitled “Method for Further Processing and Method for Operation of an Integrated Semiconductor Memory,” the entire contents of which are hereby incorporated by reference.

### BACKGROUND

Integrated semiconductor memories such as DRAM (Dynamic Random Access Memory) semiconductor memories, for example, are subjected to comprehensive functional tests after fabrication has been concluded. In the case of such functional tests, the intention is to ensure that the integrated semiconductor memory operates reliably in its intended operation if the limit values of operating parameters that are specified in a data sheet are complied with. The operating parameters include for example an external supply voltage Vₑₓₜ, which is applied externally to the integrated semiconductor memory for the purpose of supplying voltage to the integrated semiconductor memory, and also an operating frequency f, with respect to which read and write accesses to memory cells of the integrated semiconductor memory are operated synchronously. In the case of a DRAM semiconductor memory, the operating parameters furthermore include a so-called data retention time TR. This time parameter specifies the time after which a memory content that was stored in a memory cell has to be stored anew for refresh purposes.

In order to ensure the intended operation of the semiconductor memory with the operating parameters that are specified in the data sheet of the integrated semiconductor memory, the memory components, during testing, are tested below and above the limit values of the operating parameters that are specified in the data sheet. FIG. 1 shows levels of the external supply voltage Vₑₓₜ, of the frequency F, and of the data retention time TR. In order to ensure that the integrated semiconductor memory operates as intended at an external voltage Vₒₚₜ specified in the data sheet, read and write accesses are carried out at a voltage Vₘᵢₙ lower than the voltage Vₒₚₜ and a voltage Vₘₐₓ higher than the voltage Vₒₚₜ during the testing of the integrated semiconductor memory. Furthermore, the integrated semiconductor memory is operated not only at the frequency fₒₚₜ specified in the data sheet, but also at a frequency fₘᵢₙ lower than the frequency fₒₚₜ and a frequency fₘₐₓ higher than the frequency fₒₚₜ.

A further operating parameter is the data retention time. During the testing of the integrated semiconductor memory, however, the memory content is not refreshed after the data retention time TRₒₚₜ specified in the data sheet, but rather after a longer time duration TRₘₐₓ.

If the integrated semiconductor memory operates without any errors even at the higher and lower limit values of the operating parameters specified in the data sheet, it has a high quality state. Integrated semiconductor memories, by contrast, which, although they still operate without any errors in the case of the operating parameters specified in the data sheet, fail during a functional test performed by the semiconductor memory manufacturer with the higher and lower limit values of the operating parameters have a lower quality state.

Such low-quality memory chips are sold at considerable price reductions for non-critical applications. The lower-quality semiconductor memories, the so-called NC (Non Conforming) memory devices, are marked with a so-called NC marking in order to distinguish them from the higher-quality memory products, the so-called QC (Quality Conforming) memory components.

Counterfeit manufacturers repeatedly attempt, however, to sell the lower-quality NC components, by simply changing the marking, in markets which actually have high quality demands in respect of the memory components. For this purpose, the surface of a housing is blackened or ground away and the counterfeit manufacturer provides it with the marking that actually denotes the higher-quality QC memory products. The memory product originally sold as a lower-quality NC product can therefore no longer be distinguished visually from the higher-quality QC memory product.

### SUMMARY

A method for further processing of an integrated semiconductor memory is described, which makes it possible to reliably distinguish lower-quality semiconductor memories from higher-quality semiconductor memories. Furthermore, a method for operation of an integrated semiconductor memory is described, which makes it possible to establish whether the integrated semiconductor memory used is a high-quality or a lower-quality semiconductor memory. An integrated semiconductor memory whose quality state can be identified in a simple and reliable manner is also described.

In accordance with one embodiment of a method for further processing of an integrated semiconductor memory, an integrated semiconductor memory is provided with a test and production device for setting an operating parameter of the integrated semiconductor memory and for writing and reading out a data value of a datum to at least one memory cell of a memory cell array of the integrated semiconductor memory. Using the test and production device, the operating parameter is set such that the value of the operating parameter lies between a predetermined first and second limit value. A write access for writing a data value of a datum to the at least one memory cell is performed. This is followed by the performance of a read access to the at least one memory cell for reading out the data value of the datum from the memory cell which was stored during the write access. The read-out data value of the datum is compared with the previously written data value of the datum via the test and production device. At least one data bit is stored in a memory circuit of the integrated semiconductor memory with a first state if it was ascertained by the test and production device that the read-out data value of the datum is different from the previously written data value of the datum. The at least one data bit is stored in the memory circuit with a second state if it was ascertained by the test and production device that the read-out data value of the datum matches the previously written data value of the datum.

One embodiment of a method for operation of an integrated semiconductor memory provides a control unit for activating the integrated semiconductor memory for a write and/or read access to at least one memory cell of a memory cell array of the integrated semiconductor memory for storing a data value of a datum with an evaluation circuit for evaluating a state of a data bit which can be stored in a memory circuit of the integrated semiconductor memory. Firstly, the integrated semiconductor memory is activated by the control unit for performing a write and/or read access to the at least one memory cell. The state of the data bit is read out from the memory circuit of the integrated semiconductor memory by the control unit. The read-out state of the data bit is evaluated by the evaluation circuit of the control unit. The integrated semiconductor memory is deactivated if the evaluation circuit has ascertained that the data bit has the first state. A write and/or read access to the at least one memory cell is performed if the evaluation circuit has ascertained that the data bit has the second state.

According to an exemplary embodiment of the invention, an integrated semiconductor memory comprises a memory cell array comprising at least one memory cell for storing a data value of a datum and a memory circuit for storing at least one data bit. The integrated semiconductor memory has a first or a second state, wherein the integrated semiconductor memory has a first or second state, the integrated semiconductor memory has the first state if a data value of the datum can be written to the at least one memory cell during a write access and the data value of the datum stored in the memory cell can be read out from the at least one memory cell during a read access and an operating parameter of the integrated semiconductor memory lies between a predetermined first and second limit value during the write and read access. The integrated semiconductor memory has the second state if a data value of a datum which was stored in the at least one memory cell during a write access differs from the data value of the datum which is read out from the at least one memory cell during a read access following the write access and the operating parameter of the integrated semiconductor memory lies between the predetermined first and second limit values during the write and read access. The data bit is stored in the memory circuit with a first state if the integrated semiconductor memory has the first state. The data bit is stored in the memory circuit with a second state if the integrated semiconductor memory has the second state.

The above and still further features and advantages of the present invention will become apparent upon consideration of the following definitions, descriptions and descriptive figures of specific embodiments thereof wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The invention is explained in more detail below with reference to figures showing exemplary embodiments of the present invention.

FIG. 1 shows operating parameters of the integrated semiconductor memory with their limit values for ensuring intended operation of the integrated semiconductor memory.

FIG. 2 shows an embodiment of an integrated semiconductor memory for ascertaining a quality state of the integrated semiconductor memory.

FIG. 3 shows an integrated semiconductor memory with a first embodiment of a test device for testing and producing the integrated semiconductor memory.

FIG. 4 shows an integrated semiconductor memory with a second embodiment of a test device for testing and producing the integrated semiconductor memory.

FIG. 5 shows a signal flowchart of a method for testing and producing an integrated semiconductor memory.

FIG. 6 shows an integrated semiconductor memory for ascertaining a quality state of the integrated semiconductor memory with a control unit for operation of the integrated semiconductor memory.

FIG. 7 shows a signal state diagram of a method for operation of an integrated semiconductor memory.

### DETAILED DESCRIPTION

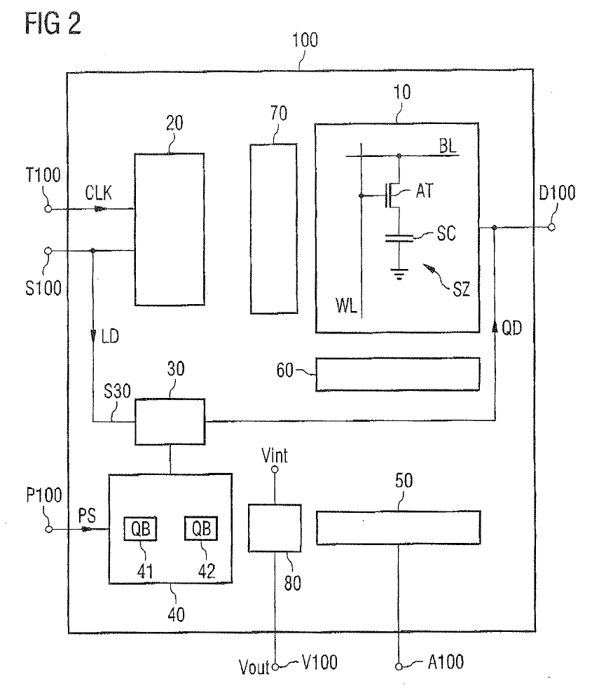

FIG. 2 shows an integrated semiconductor memory 100, in which the quality state of the integrated semiconductor memory can be ascertained in a simple and reliable manner. The integrated semiconductor memory comprises a memory cell array 10, in which memory cells SZ are arranged in matrix-like fashion between bit lines BL and word lines WL. In the case of a DRAM memory cell, the memory cell comprises a selection transistor AT and a storage capacitor SC.

For the purpose of writing information items to the memory cell and for the purpose of reading out information items from the memory cell, the memory cell SZ is activated by a control circuit 20 feeding in a high control voltage potential onto the word line WL. As a result, the selection transistor AT, embodied as an N-channel field effect transistor, for example, is controlled into the on state, with the result that the storage capacitor SC is conductively connected to the bit line BL. In the case of a write access, a datum D applied to a data terminal D100 can thus be stored via the bit line BL as charge having a high or low level in the storage capacitor SC. In the case of a read access, the storage capacitor SC is discharged via the selection transistor controlled into the on state onto the bit line BL, the potential of which is thereby altered. The change in potential is amplified by sense amplifiers (not illustrated in FIG. 2) and forwarded as data value of a datum to the data terminal D100.

For selection of a memory cell, the integrated semiconductor memory 100 has an address register 50, which is connected to an address terminal A100. A column decoder 60 evaluates a column address that is buffer-stored in the address register 50, and thereupon selects a bit line of the memory cell array 10 for a read or write access. A row decoder 70 evaluates a row address that is buffer-stored in the address register 50, and thereupon selects one of the word lines of the memory cell array 10 for performing the read and write access to that memory cell which is arranged at a crossover point between the selected word line and the selected bit line.

The control circuit 20 for controlling read and write accesses has a clock terminal T100 for application of a clock signal CLK, and a control terminal S100 for application of control signals. For operation of the integrated semiconductor memory, an external supply voltage Vₑₓₜ is applied to a supply terminal V100. An internal voltage generator 80, which is connected to the supply voltage terminal V100, generates on the output side an internal supply voltage Vᵢₙₜ for supplying components of the integrated semiconductor memory, such as the control circuit 20 or the column and row decoders 60 and 70, with the internal voltage.

Furthermore, the integrated semiconductor memory 100 is provided with a memory circuit 40 for storing at least one data bit QB. For storing the at least one data bit QB, the memory circuit 40 has an electrically programmable memory element 41, for example an E-fuse, or a memory element 42 that can be programmed via a light beam, for example a laser fuse. The memory elements 41 and 42 are preferably irreversibly programmable memory elements. If the memory circuit 40 has electrically programmable memory elements 41, the memory circuit 40 is connected to a programming terminal P100 for application of a programming signal PS. In a manner dependent on a state of the programming signal PS, the data bit QB can be stored in the programmable memory element 41 with a first or second state. In the case where laser fuses 42 are used, the data bit QB can be stored in the memory element 42 with a first or second state through irradiation of the laser fuses with a laser beam.

If the integrated semiconductor memory 100 is a lower-quality memory, the data bit QB is stored in the memory elements 41 or 42 with a first state, for example, which denotes a first quality state of the semiconductor memory 100. If the integrated semiconductor memory has a high-quality state, the data bit QB is stored in the memory elements 41 or 42 with a second state, which denotes a high-quality state of the integrated semiconductor memory 100.

A read-out circuit 30 is provided for the purpose of reading out the data bit QB from the memory elements 41 or 42. The read-out circuit 30 is driven at a control terminal S30 by a read command LD, which is fed to the integrated semiconductor memory 100 externally at the control terminal S100. If the read-out circuit 30 is driven with the read command LD, it evaluates the state of the memory elements 41 or 42 and generates an output signal QD at a data terminal D100, to which it is connected on the output side. In this case, the state of the output signal QD is dependent on the state of the data bit QB stored in the memory elements 41 and 42. Consequently, the state of the output signal QD specifies whether the integrated semiconductor memory 100 is a low-quality or high-quality semiconductor memory.

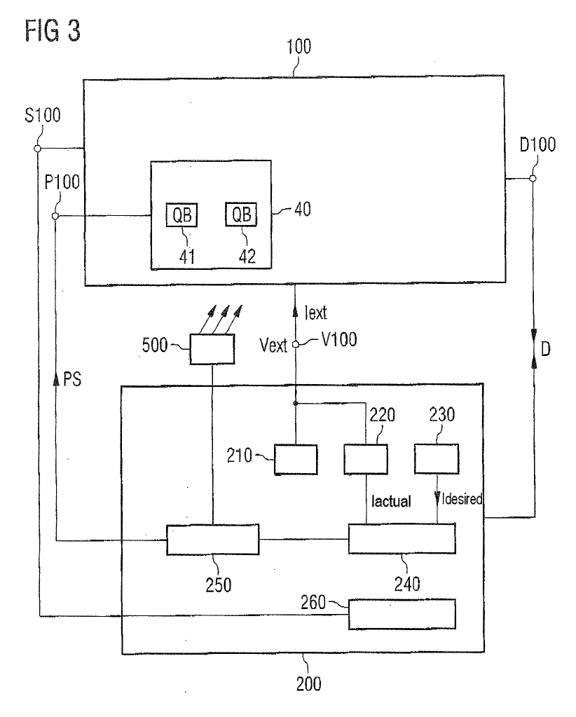

FIG. 3 shows the integrated semiconductor memory 100 from FIG. 2 in a simplified illustration. The illustration shows merely the memory circuit 40 comprising the two memory elements 41 and 42, which is connected to the programming terminal P100. The programming terminal P100 and also the data terminal D100 of the integrated semiconductor memory are connected to a test and production device 200. Furthermore, the supply voltage terminal V100 for application of the supply voltage Vₑₓₜ is connected to the test and production device 200.

The test and production device 200 has a voltage generator 210 for generating the external supply voltage Vₑₓₜ fed to the supply voltage terminal V100. The test and production device 200 furthermore has a current intensity measuring unit 220 for determining a current intensity of a current Iₑₓₜ which occurs at the supply voltage terminal V100 during intended operation. Furthermore, the test and production device 200 has a register 230, in which a desired level I_{desired} of the current intensity of the current Iₑₓₜ is stored. A control circuit 260 of the test and production device 200 drives the control terminal S100 of the integrated semiconductor memory 100 with control signals for performing read and write accesses to the memory cells of the integrated semiconductor memory 100. Data D are fed via the data terminal D100 from the test and production device to the integrated semiconductor memory 100 for storage and are fed to the test and production device 200 for evaluation during a read access.

While performing the write and read accesses for testing the semiconductor memory 100, the current intensity measuring unit 220 determines the current intensity of the current Iₑₓₜ which is fed into the integrated semiconductor memory 100 via the supply voltage terminal V100. This actual current intensity I_{actual} is compared with the desired level I_{desired} of the current intensity of the current Iₑₓₜ by a comparison circuit 240. If the determined current intensity I_{actual} of the current Iₑₓₜ lies above the desired level I_{desired} of the current Iₑₓₜ, the comparison circuit 240 drives a programming circuit 250 such that the programming circuit 250 writes a first state of the data bit QB to the memory elements 41 or 42. In the case of electrically programmable memory elements 41, it generates a state of the programming signal PS for this purpose. If the memory elements of the memory circuit 40 are embodied as laser fuses 42, the programming circuit 250 drives a laser 500 such that the latter correspondingly programs the laser fuses 42 via a laser beam.

In the example of FIG. 3, the quality state of the integrated semiconductor memory 100 depends on whether the current intensity I_{actual} of the current Iₑₓₜ which occurs at the supply voltage terminal V100 lies above or below the desired level I_{desired} of the current Iₑₓₜ. Correspondingly, either the first state of the data bit QB, which denotes a low-quality semiconductor memory, or the second state of the data bit QB, which denotes a high-quality semiconductor memory, is stored in the memory circuit 40.

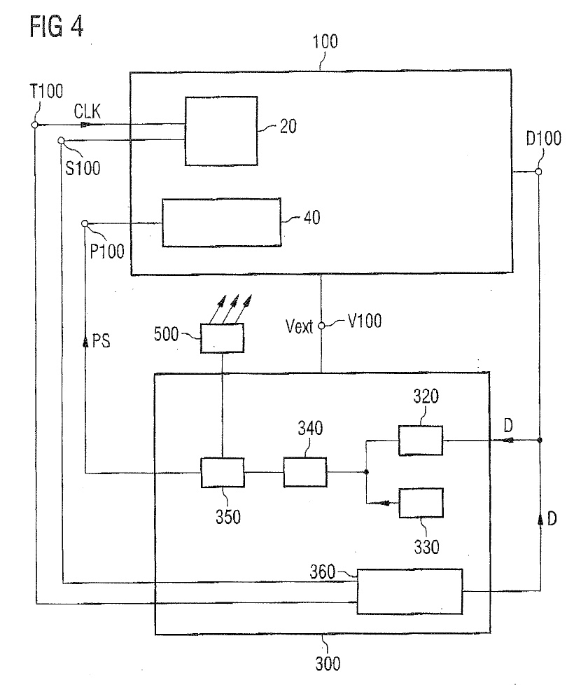

FIG. 4 shows an embodiment of a test and production device 300 connected to the integrated semiconductor memory 100. For the purpose of testing the integrated semiconductor memory, a control circuit 360 drives the control terminal S100 of the control circuit 20 with control signals for performing write and read accesses. Moreover, the control circuit 360 is connected to a clock terminal T100 for application of a clock signal CLK. Furthermore, the test and production device 300 generates an external supply voltage Vₑₓₜ fed to the supply voltage terminal V100. The level of the supply voltage Vₑₓₜ and also the frequency of the clock signal CLK are generated in variable fashion by the control circuit 360.

The arrangement illustrated in FIG. 4 can be used to test, for example, whether write and read accesses are performed without errors if the integrated semiconductor memory 100 is operated with different limit values of the clock signal CLK or different external voltage levels Vₑₓₜ. The frequency of the clock signal CLK is preferably chosen such that, in one case, it lies above a frequency fₒₚₜ specified in the data sheet for the memory 100, for example at the limit frequency fₘₐₓ, or below the frequency fₒₚₜ specified in the data sheet, for example at the limit frequency fₘᵢₙ. Likewise, the supply voltage Vₑₓₜ generated by the test and production device 300 is also chosen in such a way that a level Vₘᵢₙ lies below the supply voltage Vₒₚₜ specified in the data sheet and a further level Vₘₐₓ lies above the supply voltage Vₒₚₜ specified in the data sheet.

After data D have been fed from the control circuit 360 to the data terminal D100 for writing to the memory cells of the memory cell array, during a read access the data D are read out again from the memory cells and fed to a register 320. The register 320 is connected to a comparison circuit 340. A further register 330, in which desired data are stored, is likewise connected to the comparison circuit 340. The data read out from the memory cell array of the integrated semiconductor memory 100 can be compared with the desired data by the comparison circuit 340.

If the read-out data match the desired data despite the higher or lower frequency value fₘᵢₙ or fₘₐₓ of the clock signal CLK and despite the higher or lower limit level Vₘᵢₙ or Vₘₐₓ of the supply voltage Vₑₓₜ, a second state of the data bit QB is stored in the memory circuit 40, the second state indicating that the integrated semiconductor memory 100 is a high-quality semiconductor memory. If, by contrast, the read-out data D do not match the desired data, a state of the data bit QB which denotes a low-quality semiconductor memory 100 is stored in the memory circuit 40 by the programming circuit 350.

For this purpose, the programming circuit 350 generates, on the output side, the programming signal PS in the case of electrically irreversible memory elements 41 or a control signal fed to a laser 500 in the case where laser fuses 42 are used as memory elements of the memory circuit 40. The laser fuses 42 of the memory circuit 40 can then be programmed correspondingly by the laser 500.

For the purpose of testing a data retention time, the control circuit 360 drives the integrated semiconductor memory 100 such that the memory state of the memory cells of the memory cell array is refreshed at greater intervals than is specified by the data retention time TRₒₚₜ specified in the data sheet for memory 100. If data are nevertheless read out from the memory cells without any errors, the integrated semiconductor memory has a high-quality state. The integrated semiconductor memory is otherwise identified by a low-quality state. The programming circuit 350 programs the data bit QB in the memory circuit 40 with a first or second state in a manner corresponding to the test result.

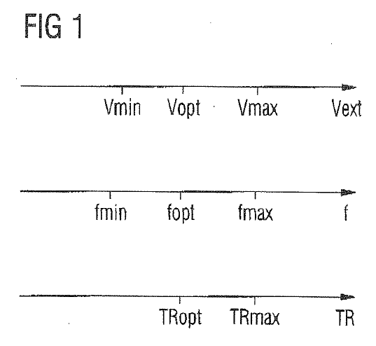

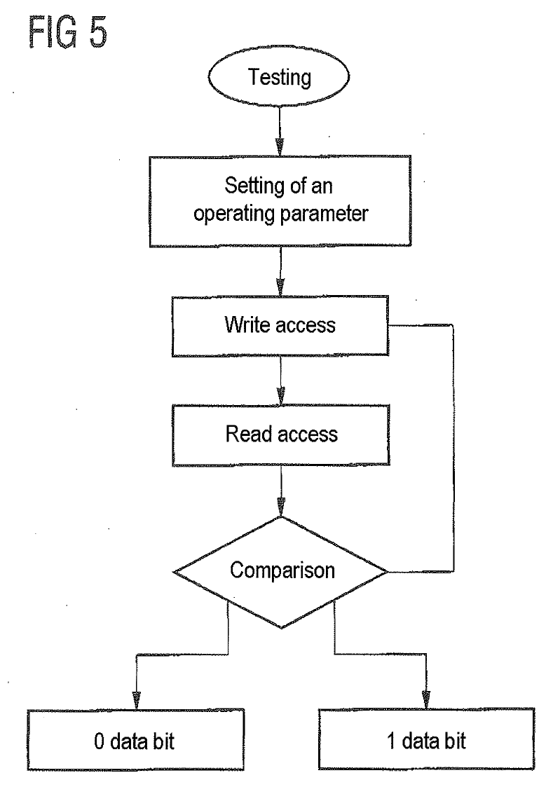

FIG. 5 shows a signal flow chart for testing and producing the integrated semiconductor memory. An operating parameter such as, for example, the external supply voltage, the operating frequency or the data retention time to be tested is predetermined by the test and production device 200 or 300. Write and read accesses to the memory cells of the integrated semiconductor memory are subsequently performed. In this case, a data value previously written in a memory cell is compared with a data value read out from the memory cell. If the two data values match, for example the data bit is stored in the memory circuit 40 with a “1” level, which denotes a high-quality semiconductor memory. If the previously written data differ from the data read out during the read access, the integrated semiconductor memory has a low-quality state. In this case, the data bit is stored with a “0” level in the memory circuit 40. In the method illustrated in FIG. 5, the operating parameters are set to the values fₘᵢₙ, fₘₐₓ or Vₘᵢₙ, Vₘₐₓ and TRₘₐₓ illustrated in FIG. 1.

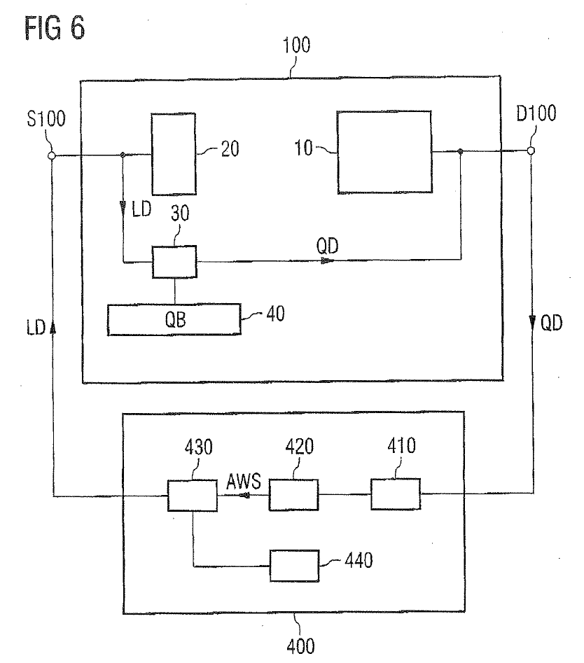

FIG. 6 shows the integrated semiconductor memory 100, which is connected to a control unit 400 in intended operation, for example in a computer application. The control unit 400 has a register circuit 410 connected to an evaluation circuit 420. A control circuit 430 is connected to the evaluation circuit 420. The control circuit 430 is connected to an output unit 440.

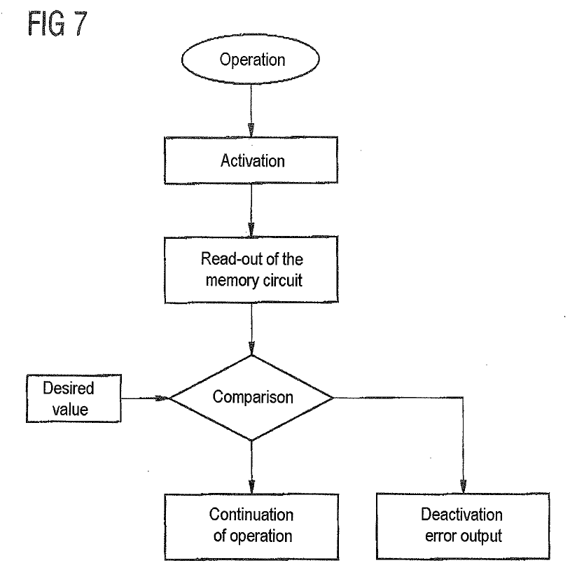

The functioning of the arrangement comprising the integrated semiconductor memory 100 and the control unit 400 is explained below with reference to FIG. 7. During operation of the integrated semiconductor memory in an application, for example a computer application, the control unit 400 is embodied as a memory controller, for example, which controls write and read accesses to the integrated semiconductor memory 100. The memory controller 400 is embodied such that upon activation of the integrated semiconductor memory 100 for a write or read access, the control circuit 430 transmits a control signal LD to the control terminal S100 of the integrated semiconductor memory.

Both the control circuit 20 and the read-out circuit 30 are connected to the control terminal S100. If the read-out circuit 30 receives the control signal LD, it reads out the present state of the data bit QB from the memory circuit 40 which was stored in the memory circuit 40 in the context of the production process of the semiconductor memory. It generates on the output side an output signal QD, the state of which is dependent on the state of the data bit QB. The output signal QD is forwarded to the data terminal D100, which is also connected to the memory cell array 10 for writing and reading out data.

The output signal QD is fed from the data terminal D100 to a register circuit 410. After buffer storage in the register circuit 410, the state of the output signal QD is evaluated by the evaluation circuit 420. The evaluation circuit 420 drives the control circuit 430 with an evaluation signal AWS in a manner dependent on the evaluated state. The evaluation signal AWS thus contains information as to whether the data bit QB is stored in the memory circuit 40 in the first state, which denotes a low-quality state, or with the second state, which denotes a high-quality memory.

The control circuit 430 is preferably embodied such that, in the case of a low-quality memory, it outputs a corresponding warning indication on the output unit 440 and, by deactivation of the integrated semiconductor memory 100, no longer executes any further write and read accesses to the memory cells of the memory cell array 10 of the integrated semiconductor memory 100. However, if the control circuit 430 is driven with a state of the evaluation signal AWS which denotes a high-quality integrated semiconductor memory 100, the operation of write and read access to the memory cells of the memory cell array 10 of the integrated semiconductor memory 100 is continued.

The integrated semiconductor memory 100 makes it possible to reliably ascertain, during operation of the integrated semiconductor memory, whether the integrated semiconductor memory has a high or low quality. The quality information stored with the data bit QB in the memory circuit 40 is preferably read out upon the start-up or first initialization of the integrated semiconductor memory 100 by the memory controller 400. However, there is also the possibility of reading out the data bit QB from the memory circuit 40 at any time during the operation of the integrated semiconductor memory and therefore of obtaining information about the quality state of the integrated semiconductor memory 100. Since the data bit QB is programmed irreversibly in the memory circuit 40 by the test and production device 200 or 300, it is made virtually impossible to subsequently falsify the quality information once it has been written.

Having described exemplary embodiments of the invention, it is believed that other modifications, variations and changes will be suggested to those skilled in the art in view of the teachings set forth herein. It is therefore to be understood that all such variations, modifications and changes are believed to fall within the scope of the present invention as defined by the appended claims. Although specific terms are employed herein, they are used in a generic and descriptive sense only and not for purposes of limitation.

What is claimed is:

1. A method of testing an integrated semiconductor memory, the method comprising:
providing a test and production device for setting an operating parameter of the integrated semiconductor memory and for writing and reading out a data value of a datum to at least one memory cell of a memory cell array of the integrated semiconductor memory;
setting the operating parameter via the test and production device such that the value of the operating parameter lies between a predetermined first and second limit value;
performing a write access for writing a data value of a datum to the at least one memory cell;
performing a read access to the at least one memory cell for reading out the data value of the datum from the memory cell, which was stored during the write access;
comparing the read-out data value of the datum with the previously written data value of the datum via the test and production device;
storing at least one data bit in a memory circuit of the integrated semiconductor memory with a first state in response to determining that the read-out data value of the datum is different from the previously written data value of the datum; and
storing the at least one data bit in the memory circuit with a second state in response to determining that the read-out data value of the datum matches the previously written data value of the datum.

2. The method as claimed in claim 1, wherein:
the integrated semiconductor memory has a first or second state;
the integrated semiconductor memory has the first state in the event the data value of the datum can be written to the at least one memory cell during the write access and the data value of the datum stored in the memory cell can be read out from the at least one memory cell during the read access and the operating parameter of the integrated semiconductor memory lies between the predetermined first and second limit values during the write and read access; and
the integrated semiconductor memory has the second state in the event the data value of the datum which was stored in the at least one memory cell during the write access differs from the data value of the datum which was read out from the at least one memory cell during the read access and the operating parameter of the integrated semiconductor memory lies between the predetermined first and second limit values during the write and read access.

3. The method as claimed in claim 1, wherein, during setting of the operating parameter, a supply voltage to the integrated semiconductor memory is set such that the value of the supply voltage lies between the predetermined first and second limit values.

4. The method as claimed in claim 1, wherein:
during performing of the write access and read access, a level of a current is determined as operating parameter at a supply voltage terminal by the test and production device;
prior to comparing the read-out data value of the datum, the determined level of the current is compared with a desired level of the current; and
storage of the at least one data bit with the first state is effected in response to determining that the read-out data value of the datum is different from the previously written data value of the datum or in response to determining that the determined level of the current lies above the desired level of the current.

5. The method as claimed in claim 1, wherein:
the data value of the datum stored in the at least one memory cell is capable of being stored anew in the at least one memory cell after a selectable time has elapsed after the storage;
the stored data value, for its data retention, is stored anew in the at least one memory cell at least after a data retention time has elapsed;
the selectable time is set such that the stored data value is stored anew in the at least one memory cell at a time after the data retention time has elapsed; and
the read access is performed after a time after the write access, wherein the time is longer than the data retention time.

6. The method as claimed in claim 1, wherein:
the read and write access is effected synchronously with a frequency of a clock signal; and
during setting of the operating parameter, the frequency of the clock signal is set such that the frequency lies between the predetermined first and second limit values.

7. The method as claimed in claim 1, further comprising:
programming at least one electrically programmable memory element of the memory circuit via a programming unit of the test and production device,
wherein, during storage of the at least one data bit, the programming unit generates a state of a programming signal for programming the electrically programmable memory element, which is supplied to a programming terminal of the memory.

8. The method as claimed in claim 1, furthering comprising:
programming at least one memory element of the memory circuit by generating a light beam by which a state of the data bit is stored in the memory element.

9. The method as claimed in claim 1, wherein the data bit is stored irreversibly in the programmable memory element.

10. A method for operating an integrated semiconductor memory, the method comprising:
providing a control unit for activating the integrated semiconductor memory for a write and/or read access to at least one memory cell of a memory cell array of the integrated semiconductor memory for storing a data value of a datum, the control unit including an evaluation circuit for evaluating a state of a data bit stored in a memory circuit of the integrated semiconductor memory;
activating the integrated semiconductor memory by the control unit for performing a write and/or read access to the at least one memory cell;
reading out the state of the data bit from the memory circuit of the integrated semiconductor memory by the control unit;
evaluating the read-out state of the data bit by the evaluation circuit of the control unit;
deactivating the integrated semiconductor memory in response to the evaluation circuit determining that the data bit has the first state; and
performance a write and/or read access to the at least one memory cell in response to the evaluation circuit determining that the data bit has the second state.

11. The method as claimed in claim 10, wherein:
the integrated semiconductor memory has a first or second state;
the integrated semiconductor memory has the first state in the event a data value of the datum can be written to the at least one memory cell during a write access and the data value of the datum stored in the memory cell can be read out from the at least one memory cell during a write access and an operating parameter of the integrated semiconductor memory lies between a predetermined first and second limit value during the write and read access;
the integrated semiconductor memory has the second state in the event a data value of a datum which was stored in the at least one memory cell during a write access differs from the data value of the datum which is read out from the at least one memory cell during a read access following the write access and the operating parameter of the integrated semiconductor memory lies between the predetermined first and second limit values during the write and read access; and
the at least one data bit is stored in the memory circuit with a first state if the integrated semiconductor memory has the first state, and the at least one data bit is stored in the memory circuit with a second state if the integrated semiconductor memory has the second state.

12. The method as claimed in claim 10, wherein:
the integrated semiconductor memory is provided with a control circuit comprising a control terminal for application of a control signal for reading out the state of the data bit of the memory circuit; and
for the read-out of the state of the data bit from the memory circuit of the integrated semiconductor memory, the control unit generates the control signal, which is supplied to the control terminal of the integrated semiconductor memory.

13. The method as claimed in claim 10, wherein during activation of the integrated semiconductor memory, a read-out circuit of the integrated semiconductor memory reads out the state of the data bit and provides the state of the data bit at an output terminal of the integrated semiconductor memory.

14. The method as claimed in claim 10, wherein the state of the data bit is provided at a data output terminal of the integrated semiconductor memory and is supplied to the control unit from the data output terminal.

15. The method as claimed in claim 10, wherein:
the control unit is provided with an output unit; and
the state of the read-out data bit is output on the output unit of the control unit.

16. An integrated semiconductor memory, comprising:
a memory cell array comprising at least one memory cell for storing a data value of a datum; and
a memory circuit for storing at least one data bit whose value indicates either a first or second state of the integrated semiconductor memory,
wherein the integrated semiconductor memory is in the first state in the event a data value of the datum can be written to the at least one memory cell during a write access and the data value of the datum stored in the memory cell can be read out from the at least one memory cell during a write access and an operating parameter of the integrated semiconductor memory lies between a predetermined first and second limit value during the write and read access, and
wherein the integrated semiconductor memory is in the second state in the event a data value of a datum which was stored in the at least one memory cell during a write access differs from the data value of the datum which is read out from the at least one memory cell during a read access following the write access and the operating parameter of the integrated semiconductor memory lies between the predetermined first and second limit values during the write and read access.

17. The integrated semiconductor memory as claimed in claim 16, further comprising:
a data output terminal for outputting a datum read out from the at least one memory cell; and
a read-out circuit for reading out the state of the data bit, wherein in response to a control signal, the read-out circuit reads out the value of the data bit from the memory circuit and generates an output signal at the data output terminal in a manner dependent on the read-out value of the data bit.

18. The integrated semiconductor memory as claimed in claim 16, wherein the memory circuit comprises at least one irreversibly programmable memory element for storing the at least one data bit.
